(19) United States
(12) Patent Application Publication
(10) Pub. No.: US 2010/0221663 A1
(43) Pub. Date: Sep. 2, 2010

(54) LIGHT SENSITIVE PLANOGRAPHIC PRINTING PLATE MATERIAL, AND IMAGE FORMATION METHOD EMPLOYING THE SAME

(75) Inventor: Hiroshi Takagi, Tokyo (JP)

Correspondence Address: CANTOR COLBURN, LLP, 20 Church Street, 22nd Floor, Hartford, CT, 06103, US

(73) Assignee: KONICA MINOLTA MEDICAL & GRAPHIC, INC., Tokyo (JP)

(21) Appl. No.: 12/279,819

(22) PCT Filed: Feb. 1, 2007
(86) PCT No.: PCT/JP2007/051679

§ 371 Date: Aug. 18, 2008

(30) Foreign Application Priority Data
Feb. 21, 2006 (JP) 2006-043554

(51) Int. Cl. G03F 7/004; G03F 7/20

(52) U.S. Cl. 430/281.1; 430/309

(57) ABSTRACT

The present invention provides a light sensitive planographic printing plate material which excels in printing durability and tone reproduction property in high resolution printing as in FM screening, and an image formation method employing the light sensitive planographic printing plate material. The light sensitive planographic printing plate material is characterized in that a light sensitive layer containing a light sensitive composition containing an addition polymerizable ethylenic double bond-containing compound, a bisimidazole compound as a photopolymerization initiator, a polymer binder and a photosensitizing dye is provided on a support obtained by subjecting one surface of an aluminum plate to (1) chemically etching treatment in an aqueous alkali solution, (2) electrochemically roughening treatment in an aqueous nitric acid solution, (3) chemically etching treatment in an aqueous alkali solution, (4) electrochemically roughening treatment in an aqueous hydrochloric acid solution, (5) chemically etching treatment in an aqueous alkali solution, and (6) anodizing treatment.

### FIELD OF THE INVENTION

The present invention relates to a light sensitive planographic printing plate material used in a computer to plate (hereinafter also referred to as CTP) system and an image formation method employing the light sensitive planographic printing plate material.

### TECHNICAL BACKGROUND

Presently, digital technique electronically processing, storing and outputting image information employing a computer has spread. In a plate making system of a planographic printing plate for off-set printing, a CTP system, which writes a digital image directly on a light sensitive planographic printing plate material employing a laser, has been developed and put into practical use.

Among them, a printing plate material comprising an aluminum support and provided thereon, an image recording layer are used in printing industries in which a relatively high printing durability is required.

As the aluminum support, an aluminum plate, which has been subjected to surface-roughening treatment, anodization treatment and optionally hydrophilization treatment, is generally used.

As a light source for image recording applied to CTP, a solid, semiconductor or gas laser with high output power, which is compact and emits an ultraviolet, visible or infrared light with an emission wavelength of from 300 to 1200 nm, is available on the market, and is put into practical use. With respect to recording materials sensitive to these various lasers, a sensitive composition applied to various reaction processes has been proposed and is practically used. Among them, in a printing field in which relatively high printing durability is required, a negative working light sensitive planographic printing plate material is known which comprises a polymerizable light sensitive layer containing a polymerizable compound (see for example, Japanese Patent O.P.I. Publication Nos. 1-105238 and 2-127404). Further, a photopolymerization type planographic printing plate material having a spectral sensitivity in the wavelength ranges of from 300 to 450 nm is known, which comprises a biimidazole compound as a photopolymerization initiator (see for example, Patent Documents 1 and 2).

There are various proposals on surface roughening treatment of an aluminum plate. A combined surface roughening treatment of electrochemically surface roughening treatment in a nitric acid electrolytic solution and electrochemically surface roughening treatment in a hydrochloric acid electrolytic solution is effective in view of printing durability and printing performance which is disclosed in Japanese Patent O.P.I. Publication Nos. 2005-254638, 2005-28867, 2005-47070, 2005-47084, 2005-1356, 2005-7751, 2005-7788 and 2005-7857.

In recent years, higher image resolution, which is an advantage of the CTP system, has progressed and printing by FM screening is widely used. High image resolution has been desired for a polymerization type light sensitive planographic printing plate material in which high printing durability has been required. A conventional polymerization type light sensitive planographic printing plate material has problem that results in increased dot gain, and is insufficient in printing durability and particularly in printing reproduction at shadow portions in a printing system as in FM screening in which dot area is small. The afore-mentioned problem occurs particularly in printing in which a VOC-free printing ink (VOC: volatile organic compound) or recycled paper has been used in view of environmental concern.

### Patent Document 1: Japanese Patent O.P.I. Publication No. 2001-194782

### Patent Document 2: Japanese Patent O.P.I. Publication No. 2003-295426

### DISCLOSURE OF THE INVENTION

### Problems to be Solved by the Invention

The present invention has been made in view of the above. An object of the invention is to provide a light sensitive planographic printing plate material which excels in printing durability and tone reproduction property in high resolution printing as in FM screening, and an image formation method employing the light sensitive planographic printing plate material.

### Means for Solving the Above Problems

The above object of the invention can be attained by the fooling constitutions.

1. A light sensitive planographic printing plate material comprising a support and provided thereon, a light sensitive layer containing a light sensitive composition containing an addition polymerizable ethylenic double bond-containing compound, a bisimidazole compound as a photopolymerization initiator, a polymer binder and a photosensitizing dye, wherein the support is obtained by subjecting one surface of an aluminum plate to (1) electrochemically roughening treatment in an aqueous nitric acid solution, (2) electrochemically roughening treatment in an aqueous hydrochloric acid solution, and (3) anodizing treatment.

2. A light sensitive planographic printing plate material comprising a support and provided thereon, a light sensitive layer containing a light sensitive composition containing an addition polymerizable ethylenic double bond-containing compound, a bisimidazole compound as a photopolymerization initiator, a polymer binder and a photosensitizing dye, wherein the support is obtained by subjecting one surface of an aluminum plate to (1) chemically etching treatment in an aqueous alkali solution, (2) electrochemically roughening treatment in an aqueous nitric acid solution, (3) chemically etching treatment in an aqueous alkali solution, (4) electrochemically roughening treatment in an aqueous hydrochloric acid solution, (5) chemically etching treatment in an aqueous alkali solution, and (6) anodizing treatment.

3. The light sensitive planographic printing plate material of item 2 above, wherein desmutting treatment is carried out after at least one of the chemically etching treatments in an aqueous alkali solution.

4. The light sensitive planographic printing plate material of any one of items 1 through 3 above, wherein hydrophilization treatment is carried out after the anodizing treatment.

5. The light sensitive planographic printing plate material of any one of items 1 through 4 above, wherein the aluminum plate has a surface with a concavo-convex pattern.

6. The light sensitive planographic printing plate material of any one of items 1 through 5 above, wherein the bisimidazole compound is represented by formula (I) below,

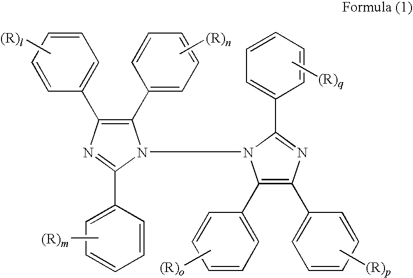

wherein R represents Cl, Br, an alkyl group having a carbon atom number of from 1 to 4 or an alkoxy group having a carbon atom number of from 1 to 4, provided that the alkyl group or alkoxy group may have a substituent; and l, m, n, o, p and q independently represent an integer of from 0 to 5, provided that when l, m, n, o, p and q are plural, plural R's may be the same or different.

7. An image formation method for a light sensitive planographic printing plate material, the method comprising the steps of imagewise exposing to a laser light the light sensitive planographic printing plate material of any one of items 1 through 6 above, and developing the exposed material with an alkaline aqueous solution with a pH of from 8.5 to 12.9 which does not substantially contain an organic solvent.

### EFFECTS OF THE INVENTION

The invention can provide a light sensitive planographic printing plate material which excels in printing durability and tone reproduction property in high resolution printing as in FM screening, particularly in printing employing a VOC-free printing ink (VOC: volatile organic compound) and an image formation method employing the light sensitive planographic printing plate material.

### PREFERRED EMBODIMENTS OF THE INVENTION

The preferred embodiments of the present invention will be explained below, but the invention is not limited thereto.

### (Support)

As the aluminum support of the invention for a planographic printing plate material, an aluminum plate is used. The aluminum plate is a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. Further, an aluminum plate manufactured by rolling can be used. A regenerated aluminum plate obtained by rolling aluminum regenerated from scrapped or recycled materials, which has recently spread, can be also used.

In the invention, the aluminum plate preferably contains Mg in amount of from 0.1 to 0.4% by weight in printing durability in view of contamination resistance. That the aluminum plate contains Mg implies that the aluminum plate contains Mg in the element composition.

### (Concavo-Convex Pattern)

An aluminum plate having a concave-convex surface formed by transferring the concavo-convex pattern on the surface may be used as the aluminum plate in the invention, or a concavo-convex surface may be formed by transferring the concave-convex pattern on the surface of an aluminum plate. A method of forming concave-convex according to rolling processing is not specifically limited but the rolling processing is preferably carried out employing a pressure roll. An aluminum plate having a concavo-convex surface, which is formed by transfer or pack rolling in the final rolling process, can be used.

Particularly is preferred a method which brings a mill roll having a concavo-convex pattern into contact with the aluminum plate surface so as to transfer the concavo-convex pattern in combination with cold rolling for adjusting to a final plate thickness or with finish rolling for obtaining a final surface configuration after adjusting to a final plate thickness, whereby a concavo-convex pattern is formed on the aluminum plate surface. For example, a method disclosed in Japanese Patent O.P.I. Publication No. 6-262203 can be suitably used.

It is especially preferred that the transfer is carried out in a conventional final cold rolling of an aluminum plate. It is preferred that rolling for the transfer is carried out through one to three passes, each of which is carried out at a roll reduction of 3 to 8%. In the invention, as a method of obtaining a transfer roll having a concavo-convex surface used in transfer of a concavo-convex pattern, a method is used which blows specific alumina particles, and an air blasting method is preferred.

The air pressure in the air blasting method is preferably from 9.81×10⁴ to 9.81×10⁵ Pa, and more preferably from 1.96×10⁵ to 4.90×10⁵ Pa. Grit materials used in the air blasting method are not specifically limited as long as they are alumina particles having a specific particle size. When hard alumina particles having acute protrusions are used as the grit materials, a deep and uniform concavo-convex pattern is likely to be formed on the surface of a transfer roll.

The average particle size of the alumina particles is from 50 to 150 μm, preferably from 60 to 130 μm, and more preferably from 70 to 90 μm. Since the alumina particles having the above average particle size range provide a transfer roll having a sufficiently large surface roughness, such a transfer roll provides a sufficiently large surface roughness to an aluminum plate, and can form a large number of pits.

Jetting in the air blasting method is carried out preferably two to five times, and more preferably two times. In the two jetting, protrusions in the non-uniform concavo-convex pattern formed at the first jetting can be ground at the second jetting, and therefore, when a concavo-convex pattern is formed on an aluminum plate surface employing a transfer roll obtained as above, deep recesses partially located on the aluminum plate surface are difficult to form. As a result, developability (sensitivity) of a planographic printing plate material is excellent. The jetting angle with respect to a jetted surface (roll surface) in the air blasting method is preferably from 60 to 120°, and more preferably from 80 to 100°.

Before plate processing as described later carried out after the air blasting processing, the roll surface is preferably grained until the average surface roughness (Ra) obtained after the air blasting processing is reduced by 10 to 40%. Graining is preferably carried out employing a sand paper, a grinding stone or a buff. Graining can form protrusions with uniform height on the transfer roll surface. When a concavo-convex pattern is formed on an aluminum plate surface employing a transfer roll obtained as above, deep recesses partially located on the aluminum plate surface are difficult to form. As a result, developability (sensitivity) of a planographic printing plate material is excellent.

The average surface roughness (Ra) of the transfer roll is preferably from 0.4 to 1.0 μm, and more preferably from 0.6 to 0.9 μm. The number of the convexes on the transfer roll surface is preferably from 1000 to 40000/mm², and more preferably from 2000 to 10000/mm². Too less number of the protrusions lowers water retention property of the support of a planographic printing plate material and adhesion of the image formation layer to the support. Lowering of the water retention property tends to cause contamination at dot image portions.

The number of the convexes on the transfer roll surface is determined from the photograph of the surface taken employing a transmission electron microscope (e.g., 2000FX TYPE, direct magnification of 5000, produced by Nippon Denshi Co., Ltd.). The average particle size is determined as follows. A negative image of the particles being read as a digital image employing a scanner, the particle sizes (circle equivalent values) of at least 300 particles are measured employing an appropriate image processing soft and then the average thereof is calculated as the average particle size. Materials for the transfer roll are not specifically limited, and may be ones used in a conventional pressure roll. In the invention, a roll made of steel is preferably used. Particularly, a roll manufactured according to cast is preferred. One preferred example of the roll material composition is as follows:

C: 0.07 to 6% by weight; Si: 0.2 to 1% by weight;
Mn: 0.15 to 1% by weight; P: not more than 0.03% by weight;

S: not more than 0.03% by weight; Cr: 2.5 to 12% by weight;

Mo: 0.05 to 1.1% by weight; Cu: not more than 0.5% by weight; V: not more than 0.5% by weight; and
Residue: Fe and impurities

Materials for the transfer roll include tool steel (SKD), high-speed steel (SKH), high carbon chromium bearing steel (SUJ) and cast steel containing carbon, chromium, molybdenum and vanadium. In order to secure long-term lifetime, a high chromium alloy cast steel containing 10 to 20% by weight of chromium can be used. Particularly, a roll according to a casting process is preferably used. Hardness of a roll after quenching and tempering is preferably from 80 to 100 in terms of Hs. The tempering is carried out at a low temperature.

The diameter of the roll is preferably from 200 to 1000 mm, and the surface length of the roll is preferably from 1000 to 4000 mm.

It is preferred that the transfer roll having a concavo-convex pattern formed on the surface according to the air blasting method is washed, followed by hardening treatment such as quenching or hard chromium plating, whereby anti-abrasion property is improved and long life-term is secured.

As hardening treatment, hard chromium plating is especially preferred. As the hard chromium plating method, an electroplating method can be used which employs a conventional CrO₃—SO₄ or CrO₃—SO₄-fluoride bath used in industrial chromium plating.

The thickness of a hard chromium plating film is preferably from 3 to 15 μm, and more preferably from 5 to 10 μm. The roll having a plating film with a thickness falling within the above range is difficult to cause film separation in which the plating film is separated from the interface between the roll surface and the film, and improves anti-abrasion property markedly. The thickness of the hard chromium plating film can be controlled by adjusting the plating treatment time.

As methods to preparing a pressure roll having a concavo-convex pattern on the surface, there can be used methods disclosed in Japanese Patent O.P.I. Publication Nos. 60-36195, 2002-251005, 60-203495, 55-74898 and 62-111792.

It is preferred that the aluminum plate with a concavo-convex pattern formed employing a pressure roll having a convex-concavo pattern on the surface has a concavo-convex structure of a pitch from 10 to 100 μm. In the above aluminum plate, the arithmetic average roughness (Ra) is preferably from 0.4 to 1.5 μm, and more preferably from 0.4 to 0.8 μm. Rmax is preferably from 1 to 6 μm, and more preferably from 2 to 5 p.m. RSm is preferably from 5 to 150 μm, and more preferably from 10 to 100 μm. The number of concave portions on the surface is preferably from 200 to 20000/mm².

The aluminum plate in the invention whose surface is formed by transfer so as to have the concavo-convex pattern used in the invention is one in a continuous strip-shaped sheet or plate form. The aluminum plate may be in the form of web, or in the sheet form in which the aluminum plate is cut to the size of a planographic printing plate material shipped as a product.

Since faults on the surface of an aluminum plate have possibility that results in defects of an aluminum support for a planographic printing plate material which is prepared from the aluminum plate, it is necessary to restrain occurrence of the faults as much as possible prior to surface processing whereby the aluminum support for a planographic printing plate material is prepared. Accordingly, when the aluminum plates are transported, they should be in the stable form in which faults are difficult to produce.

The packaging shape of an aluminum web is, for example, as follows.

Hard board and felt are placed on an iron pallet. A donut type cardboard plate is provided on both sides of a product. The product is covered with poly tubing. A wooden donut is disposed on the inner periphery of a coil around which the aluminum web is wounded, and a felt on the outer periphery of the coil. The product is tied up with an iron band and a display is carried out on the outermost surface of the product. Polyethylene film can be used as packaging material, and needle felt or hard board as buffering material.

The invention is not limited to this as long as stable transport without producing faults is possible, although there are other various packaging shapes.

The thickness of the aluminum plate used invention is from 0.1 mm to 0.6 mm, preferably from 0.15 mm to 0.4 mm, and more preferably from 0.2 mm to 0.3 mm. This thickness can be suitably varied due to the size of a printing press, the size of a planographic printing plate material or user requirements.

### (Surface Roughening)

Subsequently, surface roughening is carried out. In the invention, in some cases the aluminum plate, after a concavo-convex pattern having been transferred on the surface, is electrolytically surface roughened in an aqueous nitric acid solution, and then in an aqueous hydrochloric acid solution. However, prior to the electrolytically surface roughening, mechanical surface roughening may be carried out.

Though there is no restriction for the mechanical surface roughening method, a brushing roughening method and a honing roughening method are preferable. The brushing roughening method is carried out by rubbing the surface of the support with a rotating brush with a brush hair with a diameter of 0.2 to 0.8 mm, while supplying slurry in which volcanic ash particles with a particle size of 10 to 100 μm are dispersed in water to the surface of the support. The honing roughening method is carried out by ejecting obliquely slurry with pressure applied from nozzles to the surface of the support, the slurry containing volcanic ash particles with a particle size of 10 to 100 μm dispersed in water. A surface roughening can be also carried out by laminating a support surface with a sheet on the surface of which abrading particles with a particle size of from 10 to 100 μm was coated at intervals of 100 to 200 μm and at a density of 2.5×10³ to 10×10³/cm², and applying pressure to the sheet to transfer the roughened pattern of the sheet and roughen the surface of the support.

In some cases in the present invention, after mechanically surface-roughening treatment is conducted by a mechanical surface-roughening method, an alkali etching treatment is carried out before electrochemically surface-roughening treatment. The alkali etching treatment means a treatment in which a surface layer is dissolved by bringing the above-described aluminum plate into contact with an alkali solution.

The alkali etching treatment carried out before electrochemically surface-roughening treatment is conducted for the purpose of forming even concave portions via the electrochemical surface-roughening treatment, and of removing rolling oil on the surface of an aluminum plate (rolled aluminum), contamination, a natural oxidation film, aluminum dust generated via a mechanical surface-roughening treatment, and abrasives.

As to the alkali etching treatment, an etching amount of at least 0.1 g/m² is preferable, an etching amount of at least 0.5 g/m² is more preferable, and an etching amount of at least 1 g/m² is still more preferable. In addition, an etching amount of not more than 10 g/m² is preferable, an etching amount of not more than 8 g/m² is more preferable, an etching amount of not more than 5 g/m² is still more preferable, and an etching amount of not more than 3 g/m² is most preferable. A very small etching amount form no even pits in the electrochemical surface-roughening treatment, whereby the unevenness tends to be generated. On the other hand, a very large etching amount requires a large consumption amount of an aqueous alkali solution, resulting in an economical disadvantage.

As alkali employed for an alkali solution, for example, caustic alkali and an alkali metal salt are provided. Specific examples of the caustic alkali include sodium hydroxide and potassium hydroxide. Further, examples of the alkali metal salt include alkali metal silicate such as sodium metasilicate, sodium silicate, potassium metasilicate, potassium silicate or the like; alkali metal carbonate such as such as sodium carbonate, potassium carbonate or the like; alkali metal aluminate such as sodium aluminate, potassium aluminate or the like; alkali metal aldonate such as sodium gluconate, potassium gluconate or the like; alkali metal hydrogenphosphate such as disodium phosphate, dipotassium phosphate, trisodium phosphate, tripotassium phosphate or the like. Of these, a caustic alkali solution and a solution containing both caustic alkali and alkali metal aluminate are preferable in view of a high speed of etching and low cost. An aqueous sodium hydroxide solution is especially preferable.

As to the alkali etching treatment, the concentration of an alkali solution is preferably at least 30 g/l and more preferably at least 300 g/l. In addition, the concentration of an alkali solution is preferably not more than 500 g/l, and more not more than 450 g/l.

Further, the alkali solution preferably contains an aluminum ion. The aluminum ion concentration is preferably at least 1 g/l, and more preferably at least 50 g/l. In addition, the aluminum ion concentration is preferably not more than 200 g/l, and more preferably not more than 150 g/l. Such the alkali solution can be prepared, employing, for example, water, an aqueous 48% by weight sodium hydroxide solution and an aqueous sodium aluminate solution.

As to the alkali etching treatment, an alkali solution has a temperature of preferably at least 30° C., and more preferably at least 50° C. In addition, temperature of an alkali solution is preferably not more than 80° C., and more preferably not more than 75° C. As to the alkali etching treatment, the treatment time is preferably at least 1 second, and more preferably at least 2 seconds. In addition, a treatment time is preferably not more than 30 seconds, and more preferably not more than 15 seconds.

Examples of a method of bringing an aluminum plate into contact with an alkali solution include a method in which an aluminum plate passes through the inside of a tank charged with an alkali solution, a method in which an aluminum plate is immersed in a tank charged with an alkali solution, and a method in which an alkali solution is sprayed onto the aluminum plate surface.

It is preferred that liquid remaining on the surface of the aluminum plate after alkali etching treatment is squeegeed by a nip roller, followed by a washing treatment for 1 to 10 seconds, and liquid remaining on the aluminum plate surface is squeegeed by a nip roller.

After an aluminum plate is subjected to alkali etching treatment, the aluminum plate is preferably immersed in an acid such as a phosphoric acid, a nitric acid, a sulfuric acid, chromic acid or the like, or a mixed acid thereof to conduct a neutralization treatment (also referred to as desmutting treatment).

When electrolytically surface roughening is carried out in an electrolytic solution containing mainly nitric acid, employing alternating current, voltage applied is generally from 1 to 50 V, and preferably from 10 to 30 V. The current density used can be selected from the range from 10 to 200 A/dm², and is preferably from 20 to 100 A/dm². The quantity of electricity can be selected from the range of from 100 to 5000 C/dm², and is preferably 100 to 2000 C/dm².

The temperature during the electrolytically surface roughening may be in the range of from 10 to 50° C., and is preferably from 15 to 45° C. The nitric acid concentration in the electrolytic solution is preferably from 0.1% by weight to 5% by weight. The electrolytic solution can contain nitrates, chlorides, amines, aldehydes, phosphoric acid, chromic acid, boric acid, acetic acid, oxalic acid or an aluminum ion, as necessary.

When electrolytically surface roughening is carried out in an electrolytic solution containing mainly hydrochloric acid, employing alternating current, voltage applied is generally from 1 to 50 V, and preferably from 10 to 30 V. The hydrochloric acid concentration of the electrolytic solution is from 5 to 20 g/L, and preferably from 6.5 to 16 g/L. Temperature of the electrolytic solution is 15 to 35° C., and preferably 18 to 38° C. The aluminum ion concentration in an electrolytic solution is 0.5 to 15 g/L, and preferably 0.7 to 10 g/L. An acetic acid or a boric acid is preferably contained in an electrolytic solution, and the concentration thereof is 1 to 20 g/L, and preferably 3 to 15 g/L. The ratio with respect to the hydrochloric acid concentration is preferably 0.5 to 1.5. The current density is 15 to 120 A/dm², and preferably 20 to 90 A/dm². The quantity of electricity is 400 to 2000 C/dm², and preferably 500 to 1200 C/dm². A frequency of 40 to 150 Hz is preferably employed.

As an embodiment of the present invention, after electrolytically surface-roughening treatment, an alkali etching treatment is carried out in order to remove smut (contamination remaining on the surface) produced via the electrolytically surface-roughening treatment. This alkali etching treatment can be carried out in a similar manner as the above-described. After the alkali etching treatment, further, acid washing (desmutting treatment) is preferably carried out in order to remove the smut. The desmutting treatment is conducted by bringing an aluminum plate into contact with an acidic solution. That is, it is preferable for the plate to be dipped in an acid such as a phosphoric acid, a nitric acid, a sulfuric acid or a chromic acid, or in a mixed acid thereof, for neutralization.

As an embodiment of the present invention, after electrolytic surface-roughening treatment, the plate is treated in an acidic solution containing a phosphoric acid as a main component in order to remove smut produced via the electrolytically surface-roughening treatment. The phosphoric acid concentration is 25 to 450 g/L, and preferably 75 to 250 g/L. The acidic solution containing a phosphoric acid as a main component preferably contains an aluminum ion. The aluminum ion concentration is from 0.01 to 10 g/L, and more preferably from 1 to 5 g/L. The temperature of the acidic solution is preferably from 30 to 80° C., and more preferably from 35 to 75° C.

### (Anodizing Treatment)

After the electrolytically surface roughening, anodizing treatment is carried out. The method of conducting an anodizing treatment is not specifically limited, and commonly known methods can be used. The anodizing treatment forms an oxidation film on the support surface. Generally, the anodizing treatment is carried out in an electrolytic solution containing a sulfuric acid, a phosphoric acid or their mixture applying a direct current.

In the present invention, the anodizing treatment is preferably carried out in a sulfuric acid solution as an electrolytic solution. The sulfuric acid concentration in the electrolytic solution is preferably from 5 to 50% by weight, and more preferably from 10 to 35% by weight. The temperature is preferably from 10 to 50° C. Applied voltage is preferably not less than 18V, and more preferably not less than 20V. The current density is preferably from 1 to 30 A/dm². The quantity of electricity is preferably from 20 to 500 C/dm².

The amount of the formed anodization film is preferably from 1.0 to 10.0 mg/dm², and more preferably from 2.0 to 8.0 mg/dm². The amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water. Micro pores are formed in the anodization film, and the density of the micro pores is preferably from 400 to 700/μm², and more preferably from 400 to 600/μm².

The aluminum plate, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution.

### (Hydrophilization Processing)

In the invention, the aluminum plate obtained after the treatments above are carried out may be subjected to hydrophilization treatment as necessary. There is no restriction in particular for the method of hydrophilization treatment, and there is a method of coating on the plate water soluble resins such as polyvinyl phosphonic acid, a homopolymer or copolymer having in the side chain a sulfonic acid group, polyacrylic acid, water soluble metal salts (fro example, zinc borate), yellow dyes or amine salts. Sol-gel treatment substrate as disclosed in Japanese Patent O.P.I. Publication No. 5-304358 is used which forms a covalent bond with a functional group capable of causing addition reaction by radicals.

The hydrophilization treatment is preferably carried out employing polyvinyl phosphonic acid. As the treating methods, there are for example, a coating method, a spraying method, or a dipping method, and the invention is not limited thereto. The dipping method is preferred in that the facility is cheap. An aqueous polyvinyl phosphonic acid solution used in the dipping method is preferably an aqueous 0.05 to 3% polyvinyl phosphonic acid solution. The treatment temperature is preferably from 20 to 90° C., and the treatment time is preferably from 10 to 180 seconds. After the hydrophilization treatment, excessive polyvinyl phosphonic acid is preferably removed from the aluminum plate surface through washing or squeegeeing. After that, the resulting aluminum plate is preferably dried at preferably from 20 to 95° C.

### (Light Sensitive Layer)

### (Bisimidazole Compound)

The photopolymerization initiator in the invention is a compound capable of initiating polymerization of a polymerizable ethylenic unsaturated bond-containing compound upon imagewise exposure. The light sensitive layer in the invention contains a bisimidazole compound as a photopolymerization initiator.

The bisimidazole compound in the invention implies a hexaarylbisimidazole (HABI, a dimer of triarylimidazole) and its derivatives.

Examples of the bisimidazole compound include 2,4,5,2′,4′,5′-hexaphenylbisimidazole, 2,2′-bis(2-chlorophenyl)-4,5,4′,5′-tetraphenylbisimidazole, 2,2′-bis(2-bromophenyl)-4,5,4′,5′-tetraphenylbisimidazole, 2,2′-bis(2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,5′-tetrakis(3,4,5-trimethoxyphenyl)bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole, and 2,2′-bis(2,6-difluorophenyl)-4,5,4′,5′-tetraphenylbisimidazole.

In the invention, the bisimidazole compound represented by formula (I) above is especially effective. In formula (I), chlorine is especially preferred of chlorine and bromine represented by R.

Examples of the alkyl group having a carbon atom number of from 1 to 4 represented by R include a methyl group, an ethyl group, a propyl group, an isopropyl group, and a tert-butyl group. Examples of the alkoxy group having a carbon atom number of from 1 to 4 represented by R include a methoxy group, an ethoxy group and a propyloxy group. The substituents of the alkyl group or alkoxy group include a halogen atom, an alkoxy group, a cycloalkoxy group, an aryloxy group, an alkylthio group, a cycloalkylthio group, an alkoxycarbonyl group, an aryloxycarbonyl group, a sulfamoyl group, an acyl group, an amido group, a carbamoyl group, a ureido group, an alkylsulfonyl group, an arylsulfonyl group, an amino group, a cyano group, a nitro group and a hydroxyl group. In the invention, the substituent R is especially preferably chlorine or a methyl group.

Examples of the compound represented by formula (I) include the following compounds.

(1-1): 2,2′-Bis(2-chlorophenyl)-4,4′,5,5′-tetraphenyl-bisimidazole
(1-2): 2,2′-Bis(2-methylphenyl)-4,4′,5,5′-tetraphenyl-bisimidazole

The imidazole compound content of the light sensitive layer is preferably from 0.01 to 30% by weight, more preferably from 0.5 to 20% by weight, and still more preferably from 0.5 to 7.0% by weight, based on the light sensitive layer weight.

The light sensitive layer in the invention may contain the following polymerization initiator as a photopolymerization initiator in addition to the bisimidazole compound.

Preferred examples of a photopolymerization initiator used in combination include a titanocene compound, a monoalkyltriarylborate compound, an iron-arene complex, a polyhalogen compound and a bisimidazole compound other than the bisimidazole compound represented by formula (I) above.

As the titanocene compounds, there are compounds disclosed in Japanese Patent O.P.I. Publication Nos. 63-41483 and 2-291. Preferred examples thereof include bis(cyclopentadienyl)-Ti-dichloride, bis(cyclopentadienyl)-Ti-bisphenyl, bis(cyclopentadienyl)-Ti-bis-2,3,4,5,6-pentafluorophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 727L, produced by Ciba Specialty Co., Ltd.), bis(cyclopentadienyl)-bis(2,6-difluoro-3-(pyry-1-yl)phenyl) titanium (IRUGACURE 784, produced by Ciba Specialty Co., Ltd.), bis(cyclopentadienyl)-bis(2,4,6-trifluoro-3-(pyry-1-yl)phenyl)titanium, and bis (cyclopentadienyl)-bis(2,4,6-trifluoro-3-(2,5-dimethylpyry-1-yl)phenyl) titanium.

As the monoalkyltriaryl borate compounds, there are those described in Japanese Patent O.P.I. Publication Nos. 62-150242 and 62-143044. Preferred examples of the monoalkyl-triaryl borate compounds include tetra-n-butyl ammonium n-butyl-trinaphthalene-1-yl-borate, tetra-n-butyl ammonium n-butyl-triphenyl-borate, tetra-n-butyl ammonium n-butyl-tri-(4-tert-butylphenyl)-borate, tetra-n-butyl ammonium n-hexyl-tri-(3-chloro-4-methylphenyl)-borate, and tetra-n-butyl ammonium n-hexyl-tri-(3-fluorophenyl)-borate.

As the iron arene complexes, there are those described in Japanese Patent O.P.I. Publication No. 59-219307. Preferred examples of the iron arene complex include η-benzene-(η-cyclopentadienyl)iron hexafluorophosphate, η-cumene-(η-cyclopentadienyl)iron hexafluorophosphate, η-fluorene-(η-cyclopentadienyl)iron hexafluorophosphate, η-naphthalene-(ηcyclopentadienyl)iron hexafluorophosphate, η-xylene-(η-cyclopentadienyl)iron hexafluorophosphate, and η-benzene-(η-cyclopentadienyl)iron tetrafluoroborate.

### (Addition Polymerizable Ethylenically Double Bond-Containing Compound)

The addition polymerizable ethylenic double bond-containing compound in the invention is an ethylenic double bond-containing compound capable of being polymerized by light exposure.

As the addition polymerizable ethylenic double bond-containing compound, there are a conventional radical polymerizable monomer, and a polyfunctional monomer or oligomer having two or more of an ethylenic double bond in the molecule generally used in an ultraviolet curable resin composition.

The compound described above is not specifically limited. Preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryl-oxyethyl acrylate, tetrahydrofurfuryloxyhexanorideacrylate, an ester of 1,3-dioxane-ε-caprolactone adduct with acrylic acid, or 1,3-dioxolane acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-s-caprolactone adduct, pyrrogallol triacrylate, propionic acid dipentaerythritol triacrylate, propionic acid dipentaerythritol tetraacrylate or hydroxypivalylaldehyde modified dimethylolpropane triacrylate; a methacrylate, itaconate, crotonate or maleate alternative of the above polyfunctional acrylate.

Prepolymers can be used, and as the prepolymers, there can be used a compound described later and a prepolymer to which photopolymerization property is given by incorporating an acryloyl or methacryloyl group into an oligomer having an appropriate molecular weight. These prepolymers can be used singly, as an admixture of two or more kinds thereof, or in combination with the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate, hydroxyethylphthalyl methacrylate.xylenediisocyanate, 1,2-polybutadieneglycol.tolylenediisocyanate.2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

The light sensitive composition in the invention may contain a monomer such as a phosphazene monomer, triethylene glycol, an EO modified isocyanuric acid diacrylate, an EO modified isocyanuric acid triacrylate, dimethylol-tricyclodecane diacrylate, trimethylolpropane acrylate benzoate, an alkylene glycol acrylate, or a urethane modified acrylate, or an addition polymerizable oligomer or prepolymer having a structural unit derived from the above monomer.

As an ethylenic monomer used in combination in the invention, there is a phosphate compound having at least one (meth)acryloyl group. The phosphate compound is a compound having a (meth)acryloyl group in which at least one hydroxyl group of phosphoric acid is esterified, but is not specifically limited as long as it has a (meth)acryloyl group.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV.EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

In light sensitive composition in the invention, an addition polymerizable ethylenic double bond-containing compound having a tertiary amino group in the molecule, which is a tertiary amine monomer, is preferably used. Its molecular structure is not limited, but those are preferred in which a tertiary amine having a hydroxyl group is modified with glycidyl methacrylate, methacrylic chloride, or acrylic chloride. Examples thereof include a polymerizable compound disclosed I Japanese Patent O.P.I. Publication Nos. 1-165613, 1-203413 and 1-197213.

A reaction product of a polyhydric alcohol having a tertiary amino group in the molecule, a diisocyanate and a compound having a hydroxyl group and an addition polymerizable ethylenic double bond in the molecule is preferably used in the invention.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N,N′, N′-tetra-2-hydroxypropylethylenediamine, p-tolyldiethanolamine, N,N,N′, N′-tetra-2-hydroxyethylethylenediamine, N,N-bis(2-hydroxypropyl)aniline, allyldiethanolamine, 3-dimethylamino-1,2-propane dial, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Preferred examples of the compound having a hydroxyl group and an addition polymerizable ethylenic double bond in the molecule include 2-hydroxyethyl methacrylate, 2-hydroxyethyl acrylate, 4-hydroxybutyl acrylate, 2-hydroxypropylene-1,3-dimethacrylate, and 2-hydroxypropylene-1-methacrylate-3-acrylate.

The reaction product above can be synthesized according to the same method as a conventional method in which a urethane acrylate compound is ordinarily synthesized employing an ordinary diol, a diisocyanate and an acrylate having a hydroxyl group.

Examples of the reaction product of a polyhydric alcohol having a tertiary amino group in the molecule, a diisocyanate and a compound having a hydroxyl group and an addition polymerizable ethylenically double bond in the molecule will be listed below.

M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)

In addition to the above, acrylates or methacrylates disclosed in Japanese Patent O.P.I. Publication Nos. 1-105238 and 2-127404 can be used.

The content in the light sensitive layer of the addition polymerizable ethylenic double bond-containing compound in the invention is preferably from 30 to 70% by weight, and more preferably from 40 to 60% by weight, based on the non-volatile components of light sensitive layer.

### (Polymer Binder)

The polymer binder will be explained below.

As the polymer binder in the invention can be used a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an admixture of two or more kinds thereof.

The polymer binder is preferably a vinyl copolymer obtained by copolymerization of an acryl monomer, and more preferably a copolymer containing, as the copolymerization component, (a) a carboxyl group-containing monomer unit and (b) an alkyl methacrylate or alkyl acrylate unit.

Examples of the carboxyl group-containing monomer include an α, β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymer binder in the invention can further contain, as another monomer unit, a monomer unit derived from the monomer described in the following items (1) through (14):

1) A monomer having an aromatic hydroxy group, for example, o-, (p- or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl)methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2 chloroethyl vinyl ether, propyl vinyl ether, butyl vinyl ether, octyl vinyl ether, or phenyl vinyl ether;

8) A vinyl ester, for example, vinyl acetate, vinyl chroloacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further another monomer may be copolymerized with the above monomer.

The polymer binder is preferably a vinyl polymer having in the side chain a carboxyl group and a polymerizable double bond. As the polymer binder is also preferred an unsaturated bond-containing copolymer which is obtained by reacting a carboxyl group contained in the above vinyl copolymer molecule with for example, a compound having a (meth)acryloyl group and an epoxy group.

Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-271969.

Further, an unsaturated bond-containing vinyl copolymer which is obtained by reacting a hydroxyl group contained in the above vinyl copolymer molecule with for example, a compound having a (meth)acryloyl group and an isocyanate group is preferred as the polymer binder.

Examples of the compound having an unsaturated bond and an isocyanate group in the molecule include vinyl isocyanate, (meth)acryl isocyanate, 2-(meth)acroyloxyethyl isocyanate, m- or p-isopropenyl-α,α′-dimethylbenzyl isocyanate, and (meth)acryl isocyanate, or 2-(meth)acroyloxyethyl isocyanate is preferred.

Reaction of a carboxyl group existing in the molecule of the vinyl copolymer with a compound having in the molecule a (meth)acryloyl group and an epoxy group can be carried out according to a well-known method. For example, the reaction is carried out at a temperature of 20 to 100° C., and preferably 40 to 80° C., and more preferably at a boiling point of solvent used (while refluxing), for 2 to 10 hours and preferably 3 to 6 hours. As the solvent used in the reaction, there are solvents used in the polymerization to obtain the vinyl copolymer above. After polymerization, the solvent in the polymerization can be used without being removed from the polymerization solution as a reaction solvent used for reaction in which an aliphatic epoxy group-containing unsaturated compound is incorporated into the vinyl copolymer. The reaction can be carried out in the presence of a catalyst or a polymerization inhibitor.

As the catalyst, amines or ammonium chlorides are preferred. Examples of the amines include triethylamine, tributylamine, dimethylaminoethanol, diethylaminoethanol, methylamine, ethylamine, n-propylamine, i-propylamine, 3-methoxypropylamine, butylamine, allylamine, hexylamine, 2-ethylhexylamine, and benzylamine. Examples of the ammonium chlorides include triethylbenzylammonium chloride.

The amount used of the catalyst is ordinarily from 0.01 to 20.0% by weight based on the weight of an aliphatic epoxy group-containing unsaturated compound used. Examples of the polymerization inhibitor include hydroquinone, hydroquinone monomethyl ether, t-butylhydroquinone, 2,5-di-t-butylhydroquinone, methylhydroquinone, p-benzoquinone, methyl-p-benzoquinone, t-butyl-p-benzoquinone, and 2,5-diphenyl-p-benzoquinone. The amount used of the polymerization inhibitor is ordinarily from 0.01 to 5.0% by weight based on the weight of an aliphatic epoxy group-containing unsaturated compound used. The reaction process is controlled by measurement of the acid value of the reaction mixture and the reaction is terminated at the time when the acid value is zero.

Reaction of a hydroxyl group existing in the molecule of the vinyl copolymer with a compound having in the molecule a (meth)acryloyl group and an isocyanate group can be carried out according to a known method. For example, the reaction is carried out at a temperature of 20 to 100° C., and preferably 40 to 80° C., and more preferably at a boiling point of solvent used (while refluxing), for 2 to 10 hours and preferably 3 to 6 hours. As the solvent used in the reaction, there are solvents used in the polymerization to obtain the vinyl copolymer above. After polymerization, the solvent in the polymerization can be used without being removed from the polymerization solution as a reaction solvent used for reaction in which an isocyanate group-containing unsaturated compound is incorporated into the vinyl copolymer. The reaction can be carried out in the presence of a catalyst or a polymerization inhibitor. As the catalyst, tin compounds or amines are preferably used. Examples of thereof include dibutyltin laurate, and triethylamine.

The amount used of the catalyst is preferably from 0.01 to 20.0% by weight based on the weight of a double bond-containing compound used. Examples of the polymerization inhibitor include hydroquinone, hydroquinone monomethyl ether, t-butylhydroquinone, 2,5-di-t-butylhydroquinone, methylhydroquinone, p-benzoquinone, methyl-p-benzoquinone, t-butyl-p-benzoquinone, and 2,5-diphenyl-p-benzoquinone. The amount used of the polymerization inhibitor is ordinarily from 0.01 to 5.0% by weight based on the weight of an aliphatic epoxy group-containing unsaturated compound used.

The reaction process is controlled by measurement of infrared absorption spectra (IR) of the reaction mixture and the reaction is terminated at the time when the isocyanate absorption disappears.

The content of the vinyl polymer having in the side chain a carboxyl group and a polymerizable double bond is preferably from 50 to 100% by weight, and more preferably 100% by weight, based on the total weight of the polymer binder used.

The polymer binder content of the light sensitive layer is preferably from 10 to 90% by weight, more preferably from 15 to 70% by weight, and still more preferably from 20 to 50% by weight, in view of sensitivity.

### (Photosensitizing Dye)

A sensitizing dye used in the photopolymerization type light sensitive layer is preferably one which has an absorption maximum in the vicinity of the wavelength of light emitted from a light source used.

Examples of the dye, which has sensitivity to the wavelengths of visible to near infrared regions, i.e., an absorption maximum in the wavelength ranges of from 350 to 1300 nm, include cyanines, phthalocyanines, merocyanines, porphyrins, spiro compounds, ferrocenes, fluorenes, fulgides, imidazoles, perylenes, phenazines, phenothiazines, polyenes, azo compounds, diphenylmethanes, triphenylmethanes, polymethine acridines, cumarines, ketocumarines, quinacridones, indigos, styryl dyes, pyrylium dyes, pyrromethene dyes, pyrazolotriazole compounds, benzothiazole compounds, barbituric acid derivatives, thiobarbituric acid derivatives, ketoalcohol borate complexes, and compounds disclosed in European Patent No. 568,993, U.S. Pat. Nos. 4,508,811 and 5,227,227, and Japanese Patent O.P.I. Publication Nos. 2001-125255 and 11-271969.

Examples in which the above polymerization initiators are used in combination with the sensitizing dye are disclosed in Japanese Patent O.P.I. Publication Nos. 2001-125255 and 11-271969.

The sensitizing dye content of the light sensitive layer is preferably an amount giving a reflection density of the planographic printing plate material surface of from 0.1 to 1.2 to wavelength of light used for exposure. The sensitizing dye content giving such an amount of the image formation layer is ordinarily from 0.5 to 10% by weight, although it is different due to molecular extinction coefficient or crystallinity of dyes contained in the light sensitive layer.

### (Additives)

The light sensitive layer in the invention may contain a polymerization inhibitor in addition to the compounds described above, in order to prevent undesired polymerization of the polymerizable ethylenic double bond-containing monomer during the manufacture or storage of the light sensitive planographic printing plate material.

Examples of the polymerization inhibitor include hydroquinone, p-methoxyphenol, di-t-butyl-p-cresol, pyrrogallol, t-butylcatechol, benzoquinone, 4,4′-thiobis (3-methyl-6-t-butylphenol), 2,2′-methylenebis (4-methyl-6-t-butylphenol), N-nitrosophenylhydroxylamine cerous salt, and hindered amines such as 2,2,6,6-tetramethylpiperidine derivatives-butyl-6-(3-t-butyl-6-hydroxy-5-methylbenzyl)-4-methylphenyl acrylate.

The polymerization inhibitor content is preferably 0.01 to 5% by weight based on the total solid content of the composition above. Further, in order to prevent polymerization induced by oxygen, a higher fatty acid such as behenic acid or a higher fatty acid derivative such as behenic amide may be added to the light sensitive layer, or may be localized on the surface of the light sensitive layer in the course of drying after coating. The higher fatty acid or higher fatty acid derivative content is preferably from 0.5 to 10% by weight based on the total solid content of the composition.

Further, a colorant can be used. As the colorant can be used known materials including commercially available materials. Examples of the colorant include those described in revised edition “Ganryo Binran”, edited by Nippon Ganryo Gijutu Kyoukai (published by Seibunndou Sinkosha), or “Color Index Binran”.

As kinds of the pigments, there are black pigment, yellow pigment, red pigment, brown pigment, violet pigment, blue pigment, green pigment, fluorescent pigment, and metal powder pigment. Typical examples of the pigments include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment).

Among these pigments, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment content is preferably 0.1 to 10% by weight, and more preferably 0.2 to 5% by weight, based on the total solid content of the components above.

A purple pigment or a blue pigment is preferably utilized in view of absorption of light with the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone BC. Among them, more preferable are Phthalocyanine Blue and Dioxane Violet.

The light sensitive layer can contain surfactants as a coating improving agent as long as the performance of the invention is not jeopardized. Among these surfactants, a fluorine-contained surfactant is preferred.

Further, in order to improve physical properties of the cured light sensitive layer, the layer can contain an inorganic filler or a plasticizer such as dioctyl phthalate, dimethyl phthalate or tricresyl phosphate. The content of such a material is preferably not more than 10% by weight, based on the total solid content of the light sensitive layer.

Solvents used in the preparation of the light sensitive layer coating solution for the light sensitive layer in the invention include an alcohol such as sec-butanol, isobutanol, n-hexanol or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

The coating solution (light sensitive layer coating solution) is coated on a support according to a conventional method, and dried to obtain a photopolymerization type light sensitive planographic printing plate material. Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

The drying temperature of a coated light sensitive layer is preferably from 60 to 160° C., more preferably from 80 to 140° C., and still more preferably from 80 to 120° C.

The light sensitive coating solution is described above, and the light sensitive coating solution is coated on a support to form a light sensitive layer.

The coating amount of the light sensitive layer in the invention on a support is preferably from 0.1 to 10 g/m², and more preferably from 0.5 to 5 g/m².

### (Protective Layer (Oxygen Shielding Layer))

A protective layer is optionally provided on the light sensitive layer.

It is preferred that the protective layer (oxygen shielding layer) is highly soluble in a developer as described later (generally an alkaline solution). The protective layer preferably contains polyvinyl alcohol and polyvinyl pyrrolidone. Polyvinyl alcohol has the effect of preventing oxygen from transmitting and polyvinyl pyrrolidone has the effect of increasing adhesion between the oxygen shielding layer and the light sensitive layer adjacent thereto.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

In the light sensitive planographic printing plate material in the invention, adhesive strength between the protective layer and the light sensitive layer is preferably not less than 35 mN/mm, more preferably not less than 50 mN/mm, and still more preferably not less than 75 mN/mm. Preferred composition of the protective layer is disclosed in Japanese Patent O.P.T. Publication No. 10-10742.

The adhesive strength can be determined according to the following method. The adhesive tape with a sufficient adhesive force is applied on the protective layer, and then peeled together with the protective layer under the applied tape in the normal direction relative to the protective layer surface. Force necessary to peel the tape together with the protective layer is defined as adhesive strength.

The protective layer may further contain a surfactant or a matting agent. The protective layer is formed, coating on the photopolymerizable light sensitive layer a coating solution in which the above protective layer composition is dissolved in an appropriate coating solvent, and drying. The main solvent of the coating solution is preferably water or an alcohol solvent such as methanol, ethanol, or iso-propanol.

The coating amount of the protective layer is preferably 0.1 to 5.0 μm, and more preferably 0.5 to 3.0 μm.

The same coating method as described above in the light sensitive layer applies in the protective layer coating method. The drying temperature of the protective layer is preferably lower than that of the light sensitive layer. The former is preferably not less than 10° C. lower than that of the latter, and more preferably not less than 20° C. lower than that of the latter. The former is at most 50° C. lower than that of the latter. Further, the drying temperature of the protective layer is preferably lower than a glass transition temperature (Tg) of the binder contained in the light sensitive layer. The drying temperature of the protective layer is preferably not less than 20° C. lower than ™ of the binder contained in the light sensitive layer, and more preferably not less than 40° C. lower than Tg of the binder contained in the light sensitive layer. The drying temperature of the protective layer is preferably at most 60° C. lower than Tg of the binder contained in the light sensitive layer.

### (Imagewise Exposure)

The light sensitive planographic printing plate material of the invention is imagewise exposed to form an image, and then optionally developed to obtain a printing plate which is applied for printing.

The light sources for the imagewise exposure include, for example, a laser, an emission diode, a xenon flush lamp, a halogen lamp, a carbon arc light, a metal halide lamp, a tungsten lamp, a high pressure mercury lamp, and a non-electrode light source.

When the light sensitive planographic printing plate precursor is imagewise exposed at one time, a mask material having a negative image pattern made of a light shielding material is provided on the image formation layer to be in close contact with the image formation layer, and exposure is carried out through the mask.

When an array light such as an emission diode array is used or exposure using a halogen lamp, a metal halide lamp or a tungsten lamp is controlled using an optical shutter material such as liquid crystal or PLZT, a digital exposure according to an image signal is possible and preferable. In this case, direct writing is possible without using any mask material.

When a laser is used for exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

A laser scanning method by means of a laser beam includes a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fe lens, and sub-scanning is carried out by moving a recording medium. The method of scanning on an outer surface of a cylinder, and the method of scanning on an inner surface of a cylinder are preferred in optical system accuracy and high density recording.

### (Developer)

An imagewise exposed light sensitive layer is hardened at exposed portions, and is developed with an alkali developer, whereby the light sensitive layer at unexposed portions are removed to form an image.

As such a developer, a conventional alkali aqueous solution is used. For example, there is an alkali developer containing an inorganic alkali agent such as sodium silicate, potassium silicate, ammonium silicate, sodium secondary phosphate, potassium secondary phosphate, ammonium secondary phosphate; sodium hydrogen carbonate, potassium hydrogen carbonate, ammonium hydrogen carbonate; sodium carbonate, potassium carbonate, ammonium carbonate; sodium borate, potassium borate, lithium borate; sodium hydroxide, potassium hydroxide, and ammonium hydroxide.

The alkali developer can contain organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine.

These alkali agents can be used singly or as a mixture of two or more thereof. The alkali developer can contain an anionic surfactant, an amphoteric surfactant, or an organic solvent such as alcohol.

The alkali developer can be prepared from a developing composition in the form of tablets or granules or a developer concentrate.

The developer concentrate may be prepared by forming a developer solution, followed by evaporation to dryness and is preferably prepared in such a manner that plural components are mixed with a small amount of water or without adding any water. The developer concentrate can also be prepared in the form of granules or tablets, as described in Japanese Patent O.P.I. Publication Nos. 51-61837, 2-109042, 2-109043, 3-39735, 5-142786, 6-266062 and 7-13341. The developer concentrate may be divided into plural parts differing in material species or compounding ratio.

The developer or developer replenisher in the invention can further contain an antiseptic agent, a coloring agent, a viscosity increasing agent, an antifoaming agent, or a water softener.

In the invention, the developer is preferably an alkaline developer which does not substantially contain an organic solvent and has a pH of from 8.5 to 12.9

### (Automatic Developing Machine)

It is advantageous that an automatic developing machine is used in order to develop a light sensitive planographic printing plate material. It is preferred that the automatic developing machine is equipped with a means for automatically introducing a developer replenisher in a necessary amount into a developing bath, a means for discharging any excessive developer and a means for automatically introducing water in necessary amounts to the developing bath. It is preferred that the automatic developing machine comprises a means for detecting a planographic printing plate material to be transported, a means for calculating the area to be processed of the planographic printing plate material based on the detection, or a means for controlling a replenishing amount of a developer replenisher, a replenishing amount of water to be replenished or replenishing timing based on the detection and calculation. It is also preferred that the automatic developing machine comprises a means for controlling a temperature of a developer, a means for detecting a pH and/or electric conductivity of a developer, or a means for controlling a replenishing amount of the developer replenisher, a replenishing amount of water to be replenished and/or the replenishing timing based on the detected pH and/or electric conductivity.

It is also preferred that the automatic developing machine have a function of diluting a developer concentrate with water and a function of stirring the diluted concentrate. Where developing is followed by washing, water used for washing can be reused as a dilution water for diluting the developer concentrate.

The automatic developing machine used in the invention may be provided with a pre-processing section to allow the plate to be immersed in a pre-processing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

### (Post-Processing)

The developed printing plate material is preferably subjected to post-processing. The post-processing step comprises post-processing the developed precursor with a post-processing solution such as washing water, a rinsing solution containing a surfactant, a finisher or a protective gumming solution containing gum arabic or starch derivatives as a main component. The post-processing step is carried out employing an appropriate combination of the post-processing solution described above. For example, a method is preferred in which a developed planographic printing plate precursor is post-washed with washing water, and then processed with a rinsing solution containing a surfactant, or a developed planographic printing plate precursor is post-washed with washing water, and then processed with a finisher, since it reduces fatigue of the rinsing solution or the finisher. It is preferred that a multi-step countercurrent processing is carried out employing a rinsing solution or a finisher.

The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as dilution water for developer concentrate. In the automatic developing machine, a method is applied in which each processing solution is replenished with the respective processing replenisher according to the area of the printing plate precursor to have been processed or the operating time of the machine. A method (use-and-discard method) can be applied in which the developed printing plate material is processed with fresh processing solution and discarded. The thus obtained planographic printing plate is mounted on a printing press, and printing is carried out to obtain a large number of prints.

### (Printing)

Printing is carried out employing a conventional planographic printing press.

In recent years, printing ink containing no petroleum volatile organic compound (VOC) has been developed and used in view of environmental protection. The present invention provides excellent effects in employing such a printing ink for environmental protection.

Examples of a printing ink for environmental protection include soybean oil ink “Naturalith 100” produced by Dainippon Ink Kagaku Kogyo Co., Ltd., VOC zero ink “TK HIGH ECO NV” produced by Toyo Ink Manufacturing Co., Ltd., and process ink “Hicelvo” produced by Tokyo Ink Co., Ltd.

### EXAMPLES

Next, the present invention will be explained employing examples, but the present invention is not limited thereto. In the examples, “parts” represents “parts by weight”, unless otherwise specified.

### Example 1

### Preparation of Supports 1 Through 4

### (Aluminum Plate)

The aluminum alloy having the composition as shown later (the residue comprised of aluminum and inevitable impurities) was molten, treated and filtered. Aluminum ingot with a thickness of 500 mm and a width of 1200 mm was prepared from the resulting alloy according to a DC casting method. The resulting ingot, after scrapped off through a milling machine by a depth from the surface of an average thickness of 10 mm, was allowed to stand at 550° C. for about 5 hours, cooled to 400° C., and rolled through a hot rolling mill to prepare a rolled aluminum plate with a thickness of 2.7 mm. The resulting plate was heat-treated at 500° C. employing a continuous annealing machine and cold-rolled to prepare an aluminum plate with a thickness of 0.3 mm and a width of 1060 mm.

An aluminum alloy composition contains not less than 99.3% of Al, 0.003% of Na, 0.20% of Mg, 0.08% of Si, 0.006% of Ti, 0.004% of Mn, 0.32% of Fe, 0.004% of Ni, 0.002% of Cu, 0.015% of Zn, and 0.007% of Ga.

### (Preparation of Rolling Mill Roll)

SKD 11 steel whose composition contains 1.52% by weight of C, 0.31% by weight of Si, 0.41% by weight of Mn, 0.028% by weight of P, 0.002% by weight of S, 11.6% by weight of Cr, 1.05% by weight of Mo, 0.12% by weight of Cu, 0.27% by weight of V, and the residue including iron and inevitable impurities, was subjected to quenching and tempering to prepare a roll with a hardness Hs of 82 and an average surface roughness Ra of 0.1 μm. The resulting roll was subjected to air blasting two times and surface roughened. In the air blasting, alumina particles with an average particle size of 90 μm were used as grit materials, and the grit materials were jetted onto the surface at an angle of 90° with respect to the surface to be jetted.

Subsequently, the roll surface was polished with sandpaper until variation of the convex height of the roll surface felt within 0.1 μm. Thereafter, the polished roll was subjected to hard chromium plating to obtain a hard chrome plating film with a thickness of 8 μm. Thus, a pressure roll with an Ra of 0.65 μm was obtained.

An aluminum plate was rolled employing the above-obtained pressure roll in the final cold rolling step in the course of a rolled aluminum plate manufacturing process to form a concavo-convex pattern on the surface. The surface roughness of the rolled aluminum plate was as follows. Ra=0.5 μm, Rmax=3.0 μm, Sm=100 μm, and Δa=3.5 μm

The measurement was carried out as follows.

### <Average Roughness>

A two-dimensional roughness is measured employing a stylus roughness meter (sufcom 575, produced by Tokyo Seimitsu Co., Ltd.) and the arithmetic average roughness Ra defined according to ISO4287 is measured five times, and an average thereof is obtained as the average roughness. With respect to the reference length, the maximum height Rmax (Ry), the average distance between the concavo-convex pattern (the average value in the reference length) Sm, and an average slope Δa can be measured similarly.

### <Measurement Conditions>

Cutoff: 0.8 mm, Slope correction FLAT-ML,
Measured length: 3 mm, Longitudinal magnification: 10000,
Scanning speed: 0.3 mm/second, Stylus tip diameter: 2 μm (Alkali etching treatment prior to electrochemically surface roughening treatment)

The aluminum plate with a transferred concavo-convex pattern was immersed in a 4% sodium hydroxide solution of 50° C. for 30 seconds for etching treatment, and washed with water. The aluminum plate which was subjected to this etching treatment was immersed in an aqueous 5% nitric acid solution maintained at 25° C. for 10 seconds for desmutting treatment, and washed with water. The dissolution amount of the aluminum generated via etching was 3 g/m².

### (Electrochemically Surface Roughening Treatment)

Employing a sinusoidal waveform alternating current under conditions as shown in Table 1, the resulting aluminum plate was subjected to electrochemical surface roughening treatment in an electrolyte containing nitric acid mainly, and then in an electrolyte containing a hydrochloric acid mainly. (Alkali etching treatment after each of the electrochemically surface roughening treatments above)

After each of the electrochemically surface roughening treatments above, the resulting aluminum plate was subjected to the following Alkali etching treatment.

The aluminum plate was immersed in a 2% sodium hydroxide solution of 50° C. for 20 seconds for etching treatment, and washed with water. The aluminum plate which was subjected to this etching treatment was immersed in an aqueous 5% nitric acid solution maintained at 25° C. for 10 seconds for desmutting treatment, and washed with water. The dissolution amount of the aluminum generated via etching was 1.2 g/m².

### (Anodizing Treatment)

The aluminum plate which had been subjected to electrochemically surface roughening treatment, alkali etching treatment and then desmutting treatment, was subjected the following anodizing treatment. Employing a direct current supply, the resulting aluminum plate was subjected to anodizing treatment at 25° C. in a 200 g/L sulfuric acid aqueous solution having a dissolved aluminum concentration of 1.5 g/L at a current density of 5 A/dm² to form an anodization film weight of 30 mg/dm², and washed with water.

### (Hydrophilization Treatment)

Subsequently, the anodized aluminum plate was dipped in a 0.2% polyvinyl phosphonic acid aqueous solution at 60° C. for 40 seconds, washed with distilled water, and dried for 30 seconds employing 150° C. air to prepare supports 1 through 4.

The arithmetic average roughness (Ra) of the surface of each support obtained above was shown in Table 2.

### <Measurement of Arithmetic Surface Roughness (Ra)>

The surface roughness of the resulting supports was two-dimensionally measured employing a contact type roughness meter (SE 1700α, produced by Kosaka Kenkyusho Co., Ltd.), and the arithmetic average roughness Ra defined according to ISO4287 was measured five times, and an average thereof was obtained as the arithmetic average roughness. The measurement was carried out under the following conditions.

Cutoff: 0.8 mm, Measured length: 4 mm, Scanning speed: 0.1 mm/second, and Stylus tip diameter: 2 μm

TABLE 1

| | Electrolytic solution | | | | | | Electrol- | Quantity |
|---|---|---|---|---|---|---|---|---|
| | Hydrochlo- | Nitric | Al | Acetic | Temper- | Current | ysis | of elec- |
| Sup- | ric acid | acid | ion | acid | ature | density | time | tricity |
| port | (g/L) | (g/L) | (g/L) | (g/L) | (° C.) | (A/dm²) | (sec) | (C/dm²) |
| | First step electrolysis conditions | | | | | | | |
| 1 | | 11 | 8 | 10 | 30 | 30 | 15 | 450 |
| 2 | 11 | | 8 | 10 | 30 | 30 | 15 | 450 |
| 3 | | 11 | 8 | 10 | 30 | 45 | 20 | 900 |
| 4 | 11 | | 8 | 10 | 30 | 65 | 15 | 975 |
| | Second step electrolysis conditions | | | | | | | |
| 1 | 11 | | 8 | 10 | 30 | 30 | 10 | 300 |
| 2 | | 11 | 8 | 10 | 30 | 30 | 10 | 300 |
| 3 | | | | | | | | |
| 4 | | | | | | | | |

TABLE 2

| | Arithmetic average | |
|---|---|---|
| | roughness (Ra) | |
| Supports | (μm) | Remarks |
| 1 | 0.48 | Inventive |
| 2 | 0.50 | Comparative |
| 3 | 0.48 | Comparative |
| 4 | 0.50 | Comparative |

### [Preparation of Photopolymerization Type Planographic Printing Plate Material Samples 1 Through 16 for FD-YAG Laser (532 nm) Light Source]

The photopolymerization type light sensitive layer coating solutions 1 through 4 having the following composition were coated on each of supports 1 through 4 with a wire bar, and dried at 95° C. for 1.5 minutes so as to give a light sensitive layer with a dry thickness of 1.6 g/m². Then, the protective layer coating solution having the following composition was further coated on the resulting light sensitive layer with an applicator, and dried at 75° C. for 1.5 minutes to give a protective layer with a dry thickness of 1.7 g/m² to prepare photopolymerization type planographic printing plate material samples each having a protective layer provided on a light sensitive layer.

(Photopolymerization type light sensitive
layer coating solutions 1 through 4)

| | | |
|---|---|---|
| Polymer binder B-1 (described below) | 40.0 | parts |
| Photosensitizing dyes D1 (described below) and | 3.0 | parts |
| D2 (described below) (1:1 by weight) | | |
| Photopolymerization initiator | 4.0 | parts |
| (as shown in Table 3) | | |
| Addition polymerizable ethylenically | 40.0 | parts |
| unsaturated monomer containing a double bond | | |
| M-3 (described previously) | | |
| Addition polymerizable ethylenically | 15.0 | parts |
| unsaturated monomer containing a double bond | | |
| NK ESTER 4G (polyethylene glycol dimethacrylate | | |
| produced by Shin-Nakamura Chemical Co., Ltd.) | | |
| Hindered amine compound (LS-770 produced | 0.1 | parts |
| by Sankyo Co., Ltd.) | | |
| Trihaloalkyl compound E-1 (described below) | 1.0 | part |
| Phthalocyanine pigment (MHI 454 produced | 4.0 | parts |
| by Mikuni Color Ltd.) | | |
| Fluorine-containing surfactant (F-178K produced | 0.5 | parts |
| by Dainippon Ink Kagaku Kogyo Co., Ltd.) | | |
| Methyl ethyl ketone | 80 | parts |
| Cyclohexanone | 820 | parts |

TABLE 3

| Photopolymerization type light | | | | |
|---|---|---|---|---|
| sensitive layer coating solutions | | | | |
| for FD-YAG | | for Infrared | Photo- | |
| laser (532 nm) | for violet | laser (830 nm) | polymerization | Re- |
| light source | light source | light source | initiator | marks |
| 1 | 5 | 9 | a) | Inv. |
| 2 | 6 | 10 | b) | Inv. |
| 3 | 7 | 11 | c) | Comp. |
| 4 | 8 | 12 | d) | Comp. |

Inv.: Inventive, Comp.: Comparative
a) 2,2′-Bis(2-chlorophenyl)-4,4,5′,5′-tetraphenylbiimidazole
b) 2,2′-Bis(2-methylphenyl)-4,4,5′,5′-tetraphenylbisimidazole
c) η-Cumene-(η-cyclopentadienyl)iron hexafluorophosphate
d) Bis(cyclopentadienyl)-Ti-dichloride

### (Synthesis of Polymer Binder B-1)

One hundred and twenty-five parts (1.25 mol) of methyl methacrylate, 12 parts (0.1 mol) of ethyl methacrylate, 63 parts (0.73 mol) of methacrylic acid, 240 parts of cyclohexanone, 160 parts of isopropyl alcohol, and 5 parts of α,α′-azobisisobutyronitrile were charged in a three neck flask under nitrogen atmosphere, and reacted under nitrogen atmosphere for 6 hours at 80° C. on an oil bath to obtain a polymer. After that, 4 parts of triethylbenzylammonium chloride and 52 parts (0.73 mol) of glycidyl methacrylate were further added to the polymer, and reacted at 25° C. for 3 hours to obtain polymer binder B-1. The weight average molecular weight of the polymer binder was 55,000 (in terms of polystyrene), measured according to GPC,

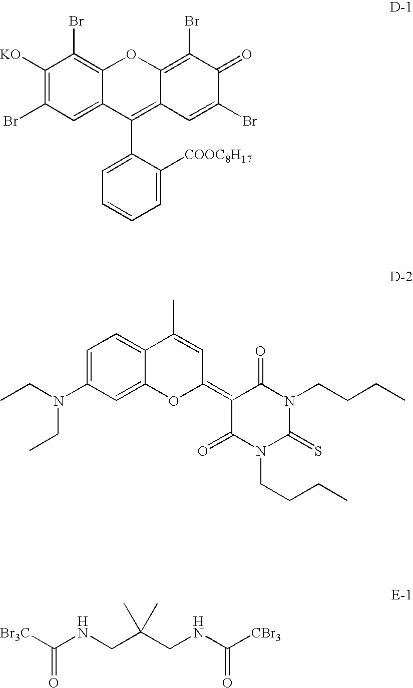

(Protective layer coating solution)

| | | |
|---|---|---|
| Polyvinyl alcohol (GL-05, produced by Nippon | 84 | parts |
| Synthetic Chemical Industry Co., Ltd.) | | |
| Polyvinyl pyrrolidone (K-30, produced | 15 | parts |
| by ISP Japan Co., Ltd.) | | |
| Surfactant (Surfinol 465, produced by Nisshin | 0.5 | parts |
| Chemical Industry Co., Ltd.) | | |
| Water | 900 | parts |

### (Image Formation)

Employing a CTP exposure device Tigercat (produced by ECRM Co., Ltd.) equipped with a FD-YAG laser light source and FM screening (FM 1 x1) installed in TurboRIP produced by IP Tech Co., Ltd, each of the photopolymerization type planographic printing plate material samples obtained above was imagewise exposed through a test pattern at 150 μJ/cm². The image for exposure included a solid image and a dot image with a dot area of 1 to 99%.

Subsequently, the exposed sample was subjected to a development treatment employing a CTP automatic developing machine (Raptor Polymer, produced by Glunz & Jensen Ltd.) fitted with a heating section before development, a pre-washing section to remove the protective layer before development, a development section charged with the following developer composition, a washing section to remove the developer remaining on the developed sample after development, and a gumming solution to protect the surface of the developed sample (a solution obtained by diluting GW-3, produced by Mitsubishi Chemical Co., Ltd., with water by a factor of 2). Thus, planographic printing plate samples 1 through 16 were obtained. Herein, the heating section was set so as to give a plate surface temperature of 105° C. for 15 seconds. Time taken from completion of exposure till introduction in the heating section of the developing machine was within 30 seconds.

Developer composition (Aqueous solution
containing the following additives)

| | |
|---|---|
| Potassium silicate solution | 40.0 g/L |
| (containing 26% by weight of SiO₂ and | |
| 13.5% by weight of K₂O) | |
| Potassium hydroxide | 4.0 g/L |
| Ethylenediaminetetraacetic acid | 0.5 g/L |
| Polyoxyethylene (13) naphthyl ether sulfonic | 20.0 g/L |
| acid salt | |

Water was added to make a 1 liter developer. PH of the developer was 12.3.

### (Printing Method)

Employing the resulting printing plate samples, printing was carried out on a press (DAIYA1F-1 produced by Mitsubishi Jukogyo Co., Ltd.), wherein printing paper, μ coat size 4/6, 90 kg (produced by Hokuetsu Seisi Co., Ltd.), printing ink (Soybean oil ink, “Naturalith 100” produced by Dainippon Ink Kagaku Co., Ltd.), and dampening water (SG-51, H solution produced by Tokyo Ink Co., Ltd., Concentration: 1.5%) were used. In this case, printing rate was 8000 sheets/hour.

### (Printing Durability of Small Dots)

The exposure was linearly corrected, and a dot image with a dot area of 1 through 99% was linearly reproduced on the resulting printing plate samples. Printing was carried out as above, and the number of prints printed until time when an image of a dot area of 5% was not reproduced was evaluated as a measure of printing durability. The more the number is, the higher the printing durability. The results are shown in Table 4.

### (Tone Reproduction Property)

The exposure was linearly corrected, and a dot image with a dot area of 1 through 99% was linearly reproduced on the resulting printing plate samples. Thereafter, printing was carried out as above, and in one thousandth print, dot images corresponding to 50% and 80% dot areas were measured through a dot meter (X-rite Dot model: CCD5, produced by Centurfax Ltd.). Dot gain at 50% and 80% dot areas (dot gain=dot area of the print−dot area of the printing plate sample before printing) was determined as a measure of tone reproduction property. The less the dot gain is, the better the tone reproduction property. The results are shown in Table 4.

TABLE 4

| | | | | Dot reproduction | | |
|---|---|---|---|---|---|---|
| Planographic | | Photopolymerization | Printing | property | | |
| printing | | type light | durability | Dot gain | Dot gain | |
| plate | Support | sensitive layer | of small dots | at 50% | at 80% | |
| No. | No. | coating solutions | Number | dot area | dot area | Remarks |
| 1 | 1 | 1 | 200000 | 8 | 4 | Inv. |
| 2 | 1 | 2 | 200000 | 8 | 4 | Inv. |
| 3 | 1 | 3 | 180000 | 8 | 10 | Comp. |
| 4 | 1 | 4 | 190000 | 8 | 10 | Comp. |
| 5 | 2 | 1 | 180000 | 12 | 8 | Comp. |
| 6 | 2 | 2 | 180000 | 12 | 8 | Comp. |
| 7 | 2 | 3 | 170000 | 12 | 12 | Comp. |
| 8 | 2 | 4 | 180000 | 12 | 12 | Comp. |
| 9 | 3 | 1 | 150000 | 15 | 14 | Comp. |
| 10 | 3 | 2 | 150000 | 15 | 14 | Comp. |
| 11 | 3 | 3 | 150000 | 15 | 15 | Comp. |
| 12 | 3 | 4 | 150000 | 15 | 15 | Comp. |
| 13 | 4 | 1 | 130000 | 18 | 16 | Comp. |
| 14 | 4 | 2 | 130000 | 18 | 16 | Comp. |
| 15 | 4 | 3 | 130000 | 19 | 17 | Comp. |
| 16 | 4 | 4 | 130000 | 19 | 18 | Comp. |

Inv.: Inventive,
Comp.: Comparative

As is apparent from Table 4, the inventive planographic printing plate material samples excel in printing durability of small dots and tone reproduction property.

### Example 2

### Preparation of Photopolymerization Type Planographic Printing Plate Material Samples 17 Through 32 for Violet Light Source

The photopolymerization type light sensitive layer coating solutions 5 through 8 having the following composition were coated on each of the supports 1 through 4 through a wire bar, and dried at 95° C. for 1.5 minutes to give a light sensitive layer with a dry thickness of 1.9 g/m². Thereafter, the protective layer coating solution described above was coated on the resulting light sensitive layer through an applicator and dried at 75° C. for 1.5 minutes to give a protective layer with a dry thickness of 1.7 g/m². Thus, photopolymerization type light sensitive planographic printing plate material samples were prepared.

(Photopolymerization type light sensitive layer coating
solutions 5 through 8)

| | |
|---|---|
| Polymer binder B-1 (described previously) | 40.0 parts |
| Photopolymerization initiator | 3.0 parts |
| (as shown in Table 3) | |
| Photosensitizing dyes D3 and D4 | 4.0 parts |
| (1:1 by weight) (described below) | |
| Addition polymerizable ethylenically | 40.0 parts |
| unsaturated monomer M-3 (described previously) | |
| Addition polymerizable ethylenically | 7.0 parts |
| unsaturated monomer NK ESTER 4G (polyethylene glycol | |
| dimethacrylate produced by Shinnakamura Kagaku Co., Ltd.) | |
| Cationically polymerizable compound C-1 | 8.0 parts |
| (described below) | |
| Hindered amine compound | 0.1 parts |
| (LS-770 produced by Sankyo Co., Ltd.) | |
| Trihaloalkyl compound B-i (described above) | 5.0 parts |
| Phthalocyanine pigment | 7.0 parts |
| (MHI 454 produced by Mikuni Sikisosha) | |
| Fluorine-contained surfactant | 0.5 parts |
| (F-178K produced by Dainippon Ink Kagaku Kogyo | |
| Co., Ltd.) | |
| Methyl ethyl ketone | 80 parts |
| Propylene glycol methyl ether | 820 parts |

D-3 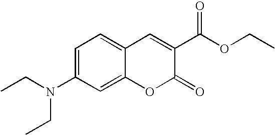
D-4 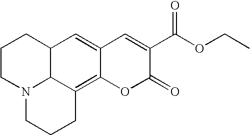
C-1

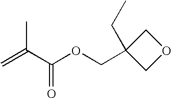

### (Image Formation)

Employing a plate setter News CTP (produced by ECRM Co., Ltd.) installed with a 405 nm laser having an output power of 30 mW, and FM screening (FM 1 x1) installed in TurboRIP produced by IP Tech Co., Ltd, each of the photopolymerization type planographic printing plate material samples obtained above was imagewise exposed through a test pattern at 50 μJ/cm². The image for exposure included a solid image and a dot image with a dot area of 1 to 99%.

Subsequently, the exposed sample was subjected to a development treatment employing a CTP automatic developing machine (Raptor Polymer, produced by Glunz & Jensen Ltd.) fitted with a heating section before development, a pre-washing section to remove the protective layer before development, a development section charged with the above-described developer composition, a washing section to remove the developer remaining on the developed sample after development, and a gumming solution to protect the surface of the developed sample (a solution obtained by diluting GW-3, produced by Mitsubishi Chemical Co., Ltd., with water by a factor of 2). Thus, planographic printing plate samples 17 through 32 were obtained. Herein, the heating device was set so as to give a plate surface temperature of 105° C. for 15 seconds. Time taken from completion of exposure till introduction in the heating section of the developing machine was within 30 seconds.

### Printing Method, Printing Durability of Small Dots, Tone Reproduction Property

Evaluation was made in the same manner as described above. The results are shown in Table 5.

TABLE 5

| | | | | Dot reproduction | | |
|---|---|---|---|---|---|---|
| Planographic | | Photopolymerization | Printing | property | | |
| printing | | type light | durability | Dot gain | Dot gain | |
| plate | Support | sensitive layer | of small dots | at 50% | at 80% | |
| No. | No. | coating solutions | Number | dot area | dot area | Remarks |
| 17 | 1 | 5 | 170000 | 8 | 4 | Inv. |
| 18 | 1 | 6 | 170000 | 8 | 4 | Inv. |
| 19 | 1 | 7 | 150000 | 8 | 10 | Comp. |
| 20 | 1 | 8 | 160000 | 8 | 10 | Comp. |
| 21 | 2 | 5 | 150000 | 12 | 8 | Comp. |
| 22 | 2 | 6 | 150000 | 12 | 8 | Comp. |
| 23 | 2 | 7 | 140000 | 12 | 12 | Comp. |
| 24 | 2 | 8 | 150000 | 12 | 12 | Comp. |
| 25 | 3 | 5 | 120000 | 15 | 14 | Comp. |
| 26 | 3 | 6 | 120000 | 15 | 14 | Comp. |
| 27 | 3 | 7 | 120000 | 15 | 15 | Comp. |
| 28 | 3 | 8 | 120000 | 15 | 15 | Comp. |
| 29 | 4 | 5 | 100000 | 18 | 16 | Comp. |
| 30 | 4 | 6 | 100000 | 18 | 16 | Comp. |
| 31 | 4 | 7 | 100000 | 19 | 17 | Comp. |
| 32 | 4 | 8 | 100000 | 19 | 18 | Comp. |

Inv.: Inventive,
Comp.: Comparative

As is apparent from Table 5, the inventive planographic printing plate material samples excel in printing durability of small dots and tone reproduction property.

### Example 3

### Preparation of Photopolymerization Type Planographic Printing Plate Material Samples 33 Through 48 for Infrared Laser (830 nm)

The photopolymerization type light sensitive layer coating solutions 9 through 12 having the following composition were coated on each of the supports 1 through 4 through a wire bar, and dried at 95° C. for 1.5 minutes to give a light sensitive layer with a dry thickness of 1.5 g/m². Thereafter, the protective layer coating solution described above was coated on the resulting light sensitive layer through an applicator and dried at 75° C. for 1.5 minutes to give a protective layer with a dry thickness of 1.7 g/m². Thus, photopolymerization type planographic printing plate material samples having a protective layer on the light sensitive layer were prepared.

(Photopolymerization type light sensitive layer coating
solutions 9 through 12)

| | |
|---|---|
| Polymer binder B-1 (described previously) | 40.0 parts |
| Photopolymerization initiator | 3.0 parts |
| as shown in Table 3 | |
| Infrared absorbing dye D-5 (described below) | 2.5 parts |
| N-Phenylglycine benzyl ester | 4.0 parts |
| Addition polymerizable ethylenically | 40.0 parts |
| unsaturated monomer M-3 (described previously) | |
| Addition polymerizable ethylenically | 7.0 parts |
| unsaturated monomer NK ESTER 4G (polyethylene glycol | |
| dimethacrylate produced by Shinnakamura Kagaku Co., Ltd.) | |
| Cationically polymerizable compound C-1 | 8.0 parts |
| (described previously) | |
| Hindered amine compound | 0.1 parts |
| (LS-770 produced by Sankyo Co., Ltd.) | |
| Trihaloalkyl compound E-1 (described above) | 5.0 parts |
| Phthalocyanine pigment | 7.0 parts |
| (MHI #4454 produced by Mikuni Sikisosha) | |
| Fluorine-contained surfactant | 0.5 parts |
| (F-178K produced by Dainippon Ink Kagaku Kogyo | |
| Co., Ltd.) | |
| Methyl ethyl ketone | 80 parts |
| Propylene glycol methyl ether | 820 parts |

D-5

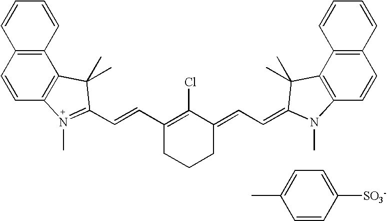

### (Image Formation)

Employing a plate setter (Trend Setter 3244 produced by Creo Co., Ltd.) installed with a 830 nm light source, and FM screening (FM 1 x1) installed in TurboRIP produced by IP Tech Co., Ltd, each of the photopolymerization type planographic printing plate material samples obtained above was imagewise exposed through a test pattern at 150 mJ/cm². The image included a solid image and a dot image with a dot area of 1 to 99%.

Subsequently, the exposed sample was subjected to development treatment employing a CTP automatic developing machine (PHW 23-V produced by Technigraph Co., Ltd.) to obtain a planographic printing plate. Herein, the developing machine comprised a heating section before development, a pre-washing section for removing the protective layer before development, a development section charged with developer as described above, a washing section for removing the developer remaining on the developed sample after development, and a gumming section charged with a gumming solution (a solution obtained by diluting GW-3, produced by Mitsubishi Chemical Co., Ltd., with water by a factor of 2) for protecting the surface of the developed sample. Thus, planographic printing plate samples 33 through 48 were obtained. Herein, the heating section was switched off, and time taken from completion of exposure till introduction in the heating section of the developing machine was within 30 seconds. (Printing method, Printing durability of small dots, Tone reproduction property)

Evaluation was made in the same manner as described above. The results are shown in Table 6.

TABLE 6

| Planographic | | Photopolymerization | Printing | Dot reproduction | | |
|---|---|---|---|---|---|---|
| printing | | type light | durability | property | | |
| plate | Support | sensitive layer | of small dots | Dot gain at | Dot gain at | |
| No. | No. | coating solutions | Number | 50% dot area | 80% dot area | Remarks |
| 33 | 1 | 9 | 150000 | 10 | 6 | Inv. |
| 34 | 1 | 10 | 150000 | 10 | 6 | Inv. |
| 35 | 1 | 11 | 130000 | 10 | 12 | Comp. |
| 36 | 1 | 12 | 140000 | 10 | 12 | Comp. |
| 37 | 2 | 9 | 130000 | 14 | 10 | Comp. |
| 38 | 2 | 10 | 130000 | 14 | 10 | Comp. |
| 39 | 2 | 11 | 120000 | 14 | 14 | Comp. |
| 40 | 2 | 12 | 130000 | 14 | 14 | Comp. |
| 41 | 3 | 9 | 100000 | 17 | 16 | Comp. |
| 42 | 3 | 10 | 100000 | 17 | 16 | Comp. |
| 43 | 3 | 11 | 100000 | 17 | 17 | Comp. |
| 44 | 3 | 12 | 100000 | 17 | 17 | Comp. |
| 45 | 4 | 9 | 80000 | 20 | 18 | Comp. |
| 46 | 4 | 10 | 80000 | 20 | 18 | Comp. |
| 47 | 4 | 11 | 80000 | 21 | 19 | Comp. |
| 48 | 4 | 12 | 80000 | 21 | 20 | Comp. |

Inv.: Inventive,
Comp.: Comparative

As is apparent from Table 6, the inventive planographic printing plate material samples excel in printing durability of small dots and tone reproduction property.

1-7. (canceled)

8. A light sensitive planographic printing plate material comprising a support and provided thereon, a light sensitive layer containing a light sensitive composition containing an addition polymerizable ethylenic double bond-containing compound, a bisimidazole compound as a photopolymerization initiator, a polymer binder and a photosensitizing dye, wherein the support is obtained by subjecting one surface of an aluminum plate to (1) electrochemically roughening treatment in an aqueous nitric acid solution, (2) electrochemically roughening treatment in an aqueous hydrochloric acid solution, and (3) anodizing treatment.

9. The light sensitive planographic printing plate material of claim 8, wherein hydrophilization treatment is carried out after the anodizing treatment.

10. The light sensitive planographic printing plate material of claim 8, wherein the aluminum plate has a surface with a concavo-convex pattern.

11. The light sensitive planographic printing plate material of claim 8, wherein the bisimidazole compound is represented by formula (1), 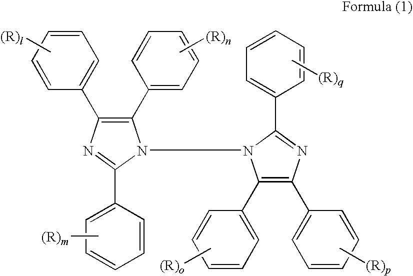
wherein R represents Cl, Br, an alkyl group having a carbon atom number of from 1 to 4 or an alkoxy group having a carbon atom number of from 1 to 4, provided that the alkyl group or alkoxy group may have a substituent; and l, m, n, o, p and q independently represent an integer of from 0 to 5, provided that when l, m, n, o, p and q are plural, plural R's may be the same or different.

12. A light sensitive planographic printing plate material comprising a support and provided thereon, a light sensitive layer containing a light sensitive composition containing an addition polymerizable ethylenic double bond-containing compound, a bisimidazole compound as a photopolymerization initiator, a polymer binder and a photosensitizing dye, wherein the support is obtained by subjecting one surface of an aluminum plate to (1) chemically etching treatment in an aqueous alkali solution, (2) electrochemically roughening treatment in an aqueous nitric acid solution, (3) chemically etching treatment in an aqueous alkali solution, (4) electrochemically roughening treatment in an aqueous hydrochloric acid solution, (5) chemically etching treatment in an aqueous alkali solution, and (6) anodizing treatment.

13. The light sensitive planographic printing plate material of claim 12, wherein desmutting treatment is carried out after at least one of the chemically etching treatments in an aqueous alkali solution.

14. The light sensitive planographic printing plate material of claim 12, wherein hydrophilization treatment is carried out after the anodizing treatment.

15. The light sensitive planographic printing plate material of claim 12, wherein the aluminum plate has a surface with a concavo-convex pattern.

16. The light sensitive planographic printing plate material of claim 12, wherein the bisimidazole compound is represented by formula (1), 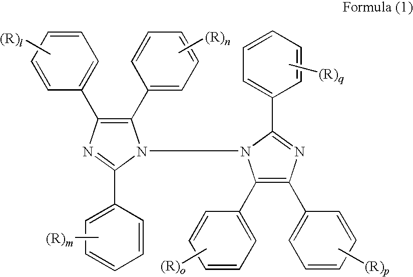
wherein R represents Cl, Br, an alkyl group having a carbon atom number of from 1 to 4 or an alkoxy group having a carbon atom number of from 1 to 4, provided that the alkyl group or alkoxy group may have a substituent; and l, m, n, o, p and q independently represent an integer of from 0 to 5, provided that when l, m, n, o, p and q are plural, plural R's may be the same or different.

17. An image formation method for a light sensitive planographic printing plate material, the method comprising the steps of imagewise exposing to a laser light the light sensitive planographic printing plate material of any one of claims 1 through, and developing the exposed material with an alkaline aqueous solution with a pH of from 8.5 to 12.9 which does not substantially contain an organic solvent.
